(19) United States
(12) Patent Application Publication
(10) Pub. No.: US 2026/0190500 A1
(43) Pub. Date: Jul. 2, 2026

(54) POWER SEMICONDUCTOR DEVICE EMBEDDED WITH SILICON CONTROLLED RECTIFIER

(71) Applicant: SK keyfoundry Inc., Cheongju-si (KR)

(72) Inventor: Youngbae KIM, Sejong-si (KR)

(73) Assignee: SK keyfoundry Inc., Cheongju-si (KR)

(21) Appl. No.: 19/229,427

(22) Filed: Jun. 5, 2025

(30) Foreign Application Priority Data
Dec. 31, 2024 (KR) 10-2024-0201682

(51) Int. Cl. H10D 89/60; H10D 84/83; H10D 84/85

(52) U.S. Cl. CPC H10D 89/713; H10D 84/835; H10D 84/85

(57) ABSTRACT

A power semiconductor device includes a junction termination region disposed between a low-side circuit region and a high-side circuit region; a high voltage lateral double diffused metal oxide semiconductor (HV LDMOS) structure disposed in the junction termination region; and a first power semiconductor device and a second power semiconductor device disposed in the high-side circuit region. The HV LDMOS structure includes a first P-type buried layer (PBL); a first P-type body region (PBODY) disposed above the first PBL; a first deep P-type well region (DPW) connecting the first PBL and the first PBODY; a first N-type well region (NW) spaced apart from the first PBODY; a first highly doped P-type (P+) body contact region disposed in the first PBODY; a first highly doped N-type (N+) source region disposed in the first PBODY; and a first N+ drain region and a first P+ drain region disposed in contact with each other.

### CROSS REFERENCE TO RELATED APPLICATIONS

This application claims the benefit under 35 U.S.C. 119(a) of Korean Patent Application No. 10-2024-0201682, filed Dec. 31, 2024, in the Korean Intellectual Property Office, the entire disclosure of which is incorporated herein by reference for all purposes.

### BACKGROUND

### 1. Field

The following description relates to a power semiconductor device embedded with silicon controlled rectifier (SCR) for electrostatic discharge (ESD) self-protection structure.

### 2. Description of the Background

The statements in this section merely provide background information related to the present disclosure and do not necessarily constitute prior art.

High voltage integrated circuits (HVICs) are used in a variety of high-voltage applications, including inverter-based variable-speed motor driver solutions, microcontroller units (MCUs), and high-voltage gate driver ICs. The HVICs may comprise various power semiconductor devices. In the motor driver solutions, the power semiconductor devices may comprise a high side gate driver IC and a low side gate driver IC with bootstrap diodes and a level shifter to operate at high voltages on the order of 600V or 1200V to drive power MOSFETs or discrete devices. While the power semiconductor device is operating, high ESD currents may flow inside the power semiconductor device. ESD structures may be desired to discharge the high ESD currents flowing inside the power semiconductor device. However, these ESD structures may require a large chip area of HVIC.

Various embodiments of the present disclosure provide HVIC semiconductor devices embedded with an SCR (silicon controlled rectifier) structure to solve the above-described problem. By doing so, various embodiments of the present disclosure aim to provide an HVIC semiconductor device capable of improving the ESD robustness without adding a separate ESD structure.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a power semiconductor device includes a low-side circuit region and a high-side circuit region disposed on a semiconductor substrate; a junction termination region disposed between the low-side circuit region and the high-side circuit region; a high voltage lateral double diffused metal oxide semiconductor (HV LDMOS) structure disposed in the junction termination region; and a first power semiconductor device and a second power semiconductor device disposed in the high-side circuit region. The HV LDMOS structure includes a first P-type buried layer (PBL) disposed on the semiconductor substrate; a first P-type body region (PBODY) disposed above the first PBL; a first deep P-type well region (DPW) connecting the first PBL and the first PBODY; a first N-type well region (NW) spaced apart from the first PBODY; a first highly doped P-type (P+) body contact region disposed in the first PBODY; a first highly doped N-type (N+) source region disposed in the first PBODY; and a first N+ drain region and a first P+ drain region disposed in contact with each other in the first NW.

The HV LDMOS structure may further include a deep N-type well region (DNW) disposed on the semiconductor substrate; a first field oxide layer (FOX) and a first gate insulating layer disposed between the first N+ source region and the first N+ drain region; a first gate electrode disposed on a portion of the first FOX and the first gate insulating layer; a first field plate disposed on another portion of the first FOX and electrically coupled to the first N+ drain region and the first P+ drain region; a first P-type top region (PTOP) disposed below the first FOX; and a first N-type buried layer (NBL) disposed below the first NW, the first N+ drain region, and the first P+ drain region.

The junction termination region may include a second PBL disposed on the semiconductor substrate; a second PBODY disposed above the second PBL; a second DPW connecting the second PBL and the second PBODY; a second NW spaced apart from the second PBODY; a second N+ source region and a second P+ body contact region disposed in contact with each other in the second PBODY; a second N+ drain region and a second P+ drain region disposed in contact with each other in the second NW; a second FOX and a second gate insulating layer disposed between the second N+ source region and the second N+ drain region; a second gate electrode 236 disposed on a portion of the second FOX 218 and the second gate insulating layer; a second field plate disposed on the second FOX and electrically coupled to the second N+ drain region and the second P+ drain region; and a second PTOP disposed below the second FOX.

The power semiconductor device may further include a first guard ring (GR) adjacent to the HV LDMOS structure. The first GR may include a first GR N-type buried layer (NBL) disposed on the semiconductor substrate; a first GR P-type buried layer (PBL) disposed on the semiconductor substrate; a first GR N-type well region (NW) disposed on the first GR NBL; a first GR deep P-type well region (DPW) disposed on the first GR PBL; a first GR N+ region disposed in the first GR NW; and a first GR P+ region disposed in the first GR DPW.

The power semiconductor device may further include a second GR disposed in the junction termination region. The second GR may include a second GR NBL disposed on the semiconductor substrate; a second GR PBL disposed on the semiconductor substrate; a second GR NW disposed on the second GR NBL; a second GR DPW disposed on the second GR PBL; a second GR N+ region disposed in the second GR NW; and a second GR P+ region disposed in the second GR DPW.

The power semiconductor device may further include a first isolation region disposed between the HV LDMOS structure and the high-side circuit region; and a second isolation region disposed between the high-side circuit region and the junction termination region. Each of the first isolation region and the second isolation region may include an isolation P-type buried layer (ISO PBL) disposed over the semiconductor substrate; an isolation deep P-type well region (ISO DPW) disposed on the ISO PBL; and an isolation field oxide layer (ISO FOX) disposed on the ISO DPW.

The power semiconductor device may further include a first silicide layer disposed on the first N+ drain region and the first P+ drain region of the HV LDMOS structure; and a second silicide layer disposed on the second N+ source region and the second P+ body contact region of the junction isolation region. The first N+ drain region may be fully covered by the first silicide layer, and the first P+ drain region may be partially covered by the first silicide layer. The second P+ body contact region may be fully covered by the second silicide layer, and the second N+ source region may be partially covered by the second silicide layer.

The HV LDMOS structure may further include a third PBODY disposed between the first PBODY and the first NW; and a first P+ region, a first N+ region and a second P+ region disposed in the third PBODY.

The first power semiconductor device may be an N-type extended drain metal oxide semiconductor (nEDMOS) structure including a first high voltage N-type buried layer (HV NBL) disposed on the semiconductor substrate; a first high voltage P-type buried layer (HV PBL) disposed on the first HV NBL; a high voltage deep P-type well region (HV DPW) disposed on the first HV PBL; a HV N+ source region and an HV N+ drain region disposed in the HV DPW; a first HV gate insulating layer disposed between the HV N+ source region and the HV N+ drain region; and a first HV gate electrode disposed on the first HV gate insulating layer.

The second power semiconductor device may be a P-type extended drain metal oxide semiconductor (pEDMOS) structure including a second HV NBL disposed on the semiconductor substrate; an HV deep N-type well region (HV DNW) disposed on the second HV NBL; a HV P+ source region and a HV P+ drain region disposed in the HV DNW; a second HV gate insulating layer disposed between the HV P+ source region and the HV P+ drain region; and a second HV gate electrode disposed on the second HV gate insulating layer.

In another general aspect, a power semiconductor device includes a low-side circuit region and a high-side circuit region disposed on a semiconductor substrate; a junction termination region disposed between the low-side circuit region and the high-side circuit region; a high voltage lateral double diffused metal oxide semiconductor (HV LDMOS) structure disposed in the junction termination region; and a first power semiconductor device and a second power semiconductor device disposed in the high-side circuit region. The HV LDMOS structure includes a first P-type buried layer (PBL) disposed on the semiconductor substrate; a first P-type body region (PBODY) disposed above the first PBL; a first deep P-type well region (DPW) connecting the first PBL and the first PBODY; a first N-type well region (NW) spaced apart from the first PBODY; a first ESD self-protection structure disposed in the first PBODY; and a second ESD self-protection structure, disposed in the first NW, including a first P+ drain region forming a first embedded SCR structure.

The second ESD self-protection structure may further include a first N+ drain region and the first P+ drain region disposed in contact with each other in the first NW.

The first ESD self-protection structure may include a first highly doped P-type (P+) body contact region disposed in the first PBODY, and a first highly doped N-type (N+) source region disposed in the first PBODY.

The junction termination region may include a second PBL disposed on the semiconductor substrate; a second PBODY disposed above the second PBL; a second DPW connecting the second PBL and the second PBODY; a second NW spaced apart from the second PBODY; a second N+ source region and a second P+ body contact region disposed in contact with each other in the second PBODY; a second N+ drain region and a second P+ drain region disposed in contact with each other in the second NW; a second FOX and a second gate insulating layer disposed between the second N+ source region and the second N+ drain region; a second gate electrode disposed on a portion of the second FOX and the second gate insulating layer; a second field plate disposed on the second FOX and electrically coupled to the second N+ drain region and the second P+ drain region; and a second PTOP disposed below the second FOX.

Other features and aspects will be apparent from the following detailed description, the drawings, and the claims.

### BRIEF DESCRIPTION OF DRAWINGS

FIG. 1 illustrates a plan view of a power semiconductor device which comprises an ESD self-protection structure according to an embodiment.

FIG. 2 illustrates a cross-sectional view taken along A-A line in FIG. 1 according to one embodiment of the present disclosure.

FIGS. 3a and 3b illustrate ESD current flow diagrams of a power semiconductor device which comprises an ESD self-protection structure according to an embodiment.

FIG. 4 illustrates a cross-sectional view of a power semiconductor device which comprises an ESD self-protection structure according to another embodiment.

FIG. 5 illustrates a cross-sectional view of a power semiconductor device which comprises an ESD self-protection structure according to another embodiment.

FIG. 6 illustrates a cross-sectional view of a plurality of high power semiconductor devices according to an embodiment of the present disclosure.

FIG. 7 illustrates a high voltage integrated circuit diagram to which an embodiment of the present disclosure can be applied.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

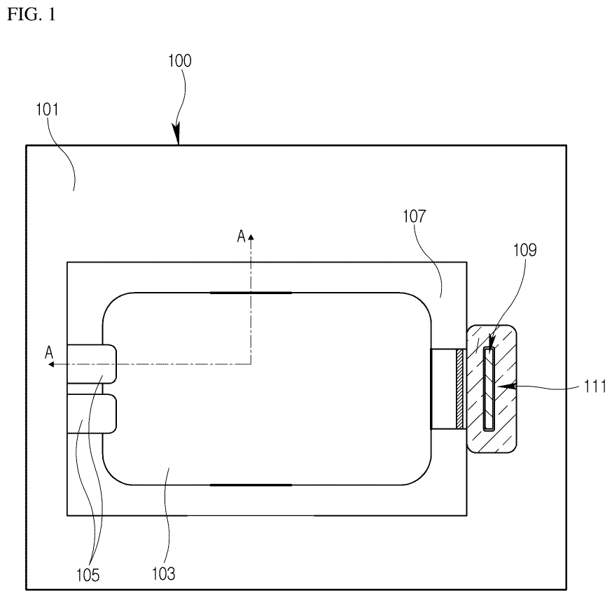

FIG. 1 illustrates a plan view of a power semiconductor device which comprises an ESD self-protection structure according to an embodiment of the present disclosure.

Referring to FIG. 1, an HVIC (high voltage integrated circuit) 100 may comprise a low-side circuit region 101 and a high-side circuit region 103. The low-side circuit region 101 and the high-side circuit region 103 may refer to as a low-voltage power domain and a high-voltage power domain, respectively. The low-side circuit region 101 may comprise a low voltage device having a low potential energy. The high-side circuit region 103 may comprise a high voltage device having a higher potential energy than that of the low voltage device. Therefore, the low-side circuit region 101 and the high-side circuit region 103 may refer to a low voltage region and a high voltage region, respectively.

The HVIC (high voltage integrated circuit) 100 may further comprise level shifters 105 disposed between the low-side circuit region 101 and the high-side circuit region 103. The level shifters 105 may level shift a high-side control signal between the low-side circuit region 101 and the high-side circuit region 103. The level shifters 105 may be configured to generate, based on a set control signal, an output control signal having a first amplitude greater than a second amplitude of an input control signal. The level shifters 105 may also be configured to send the output control signal to the switch driver. An output control signal transmission from the low-side circuit region 110 to the high-side circuit region 120 is performed by the level shifters 105. The level shifters 105 may comprise an N-type or a P-type lateral double diffused MOS (nLDMOS or pLDMOS) structure or an extended drain MOS (nEDMOS or pEDMOS) structure for the output control signal transmission.

The HVIC 100 may further comprise a high voltage junction termination region (HV JTR) 107 disposed to surround the high-side circuit region 103. The HV JTR 107 may provide an electrical isolation between the low-side circuit region 101 and the high-side circuit region 103.

The HVIC 100 may further comprise a bootstrap diode 109 surrounded by a guard ring structure 111. Here, the bootstrap diode 109 may be replaced by a PN diode or a Schottky diode. The guard ring structure 111 may enclose the bootstrap diode 109 to isolate the bootstrap diode 109 adjacent from parasitic structures that may trigger latch-up.

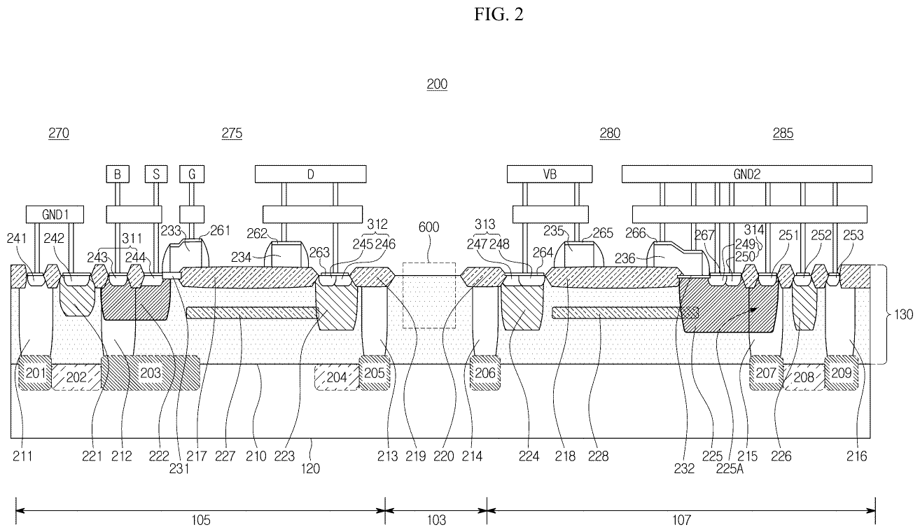

FIG. 2 illustrates a cross-sectional view taken along A-A line in FIG. 1 according to one embodiment of the present disclosure.

Referring to FIG. 2, a power semiconductor device 200 may be divided by the high-side circuit region 103, the level shifters 105, and the HV JTR 107. A first isolation region may be disposed between the level shifters 105 and the high-side circuit region 103. A second isolation region may be disposed between the high-side circuit region 103 and the HV JTR 107.

The level shifters 105 may comprise a first guard ring 270 and a first high voltage structure 275 adjacent to the first guard ring 270. The level shifters 105 serve to transfer a signal from the low-side circuit region 101 to the high-side circuit region 103. For example, an output control signal transmission from the low-side circuit region 103 to the high-side circuit region 105 may be performed by the level shifters 105.

The first guard ring 270 may comprise a first guard ring P-type buried layer (GR PBL) 201, a first guard ring N-type buried layer (GR NBL) 202, a first guard ring deep P-type well region (GR DPW) 211, a first guard ring N-type well region (GR NW) 221, a first guard ring highly doped P-type region (GR P+ region) 241, a first guard ring highly doped N-type region (GR N+ region) 242. The GR P+ region 241 and the GR N+ region 242 may be electrically coupled to a first ground voltage GND1, such that the first guard ring 270 may be electrically coupled to the first ground voltage GND1.

In the first guard ring 270, the first GR PBL 201 and the first GR NBL 202 may be disposed in contact with each other. The first GR NW 221 may be disposed on the first GR NBL 202. The first GR DPW 211 may be disposed on the first GR PBL 201. The first GR P+ region 241 may be disposed in the first GR DPW 211. The first GR N+ region 242 may be disposed in the first GR NW 221. A field oxide layer (FOX) may be disposed between the first GR P+ region 241 and the first GR N+ region 242.

The first high voltage structure 275 may comprise an nLDMOS, a pLDMOS, an nEDMOS, or a pEDMOS. Herein, the high voltage nLDMOS structure may be implemented for the first high voltage structure 275. The first high voltage structure 275 may comprise a first P-type buried layer (PBL) 203, a first N-type buried layer (NBL) 204, a deep N-type well region (DNW) 210, a first deep P-type well region (DPW) 212, a first field oxide layer (FOX) 217, a first P-type body region (PBODY) 222, a first N-type well region (NW) 223, a first P-type top region (PTOP) 227, a first gate insulating layer 231, a first gate electrode 233, a first field plate 234, a first highly doped P-type body contact region (P+ body contact region) 243, a first highly doped N-type source region (N+ source region) 244, a first highly doped P-type drain region (P+ drain region) 245, a first highly doped N-type drain region (N+ drain region) 246, a first source silicide layer (reference numeral not provided) disposed on the first N+ source region 244, a first gate silicide layer 261, a first field plate silicide layer 262, and a first drain silicide layer 263.

In the high voltage structure 275, the P+ body contact region 243 and the first N+ source region 244 become a first ESD self-protection structure 311. The P+ drain region 245 and the first N+ drain region 246 become a second ESD self-protection structure 312.

Here, the first DPW 212 is disposed to connect the first PBODY 222 to the first PBL 203. The first DPW 212 may vertically connect the first PBL 203 and the first PBODY 222. The first NBL 204 is disposed below the first N+ drain region 246 and the first P+ drain region 245 so as to prevent leakage of a current into the substrate 120.

The first P+ body contact region 243 and the first N+ source region 244 are disposed in the first PBODY 222. The first P+ body contact region 243 and the first N+ source region 244 may be electrically coupled to each other, and a source terminal S or a body terminal B may be coupled thereto. Alternatively, the first P+ body contact region 243 and the first N+ source region 244 may be electrically isolated, and a source terminal S or a body terminal B may be coupled to each thereof.

The first gate insulating layer 231 and the thick first FOX 217 are disposed between the first N+ source region 244 and the first N+ drain region 246. The first gate electrode 233 is disposed on the first FOX 217 and the first gate insulating layer 231. A first gate terminal G is connected to the first gate electrode 233.

The first PTOP 227 is disposed below the first FOX 217. In a reverse bias state, the first PTOP 227 may assist in the extension of depletion regions. In addition, the first PTOP 227 may help reduce the surface electric field (RESURF) between the first ESD self-protection structure 311 and the second ESD self-protection structure 312.

The first NW 223 is disposed to be spaced apart from the first PBODY 222. The first P+ drain region 245 and the first N+ drain region 246 are disposed in contact with each other in the first NW 223. The first field plate 234 is disposed on the first FOX 217. The first field plate 234, the first P+ drain region 245, and the first N+ drain region 246 are electrically coupled to one another, and a drain terminal D may be coupled thereto.

As described above, the first isolation region may be disposed between the high-side circuit region 103 and the level shifters 105. The first isolation region may comprise a first isolation P-type buried layer (ISO PBL) 205, a first isolation deep P-type well region (ISO DPW) 213, and a first isolation field oxide layer (ISO FOX) 219 to electrically isolate the high-side circuit region 103 from the level shifters 105.

As described above, the second isolation region may be disposed between the high-side circuit region 103 and the HV JTR 107. The second isolation region may comprise a second ISO PBL 206, a second ISO DPW 214, and a second ISO FOX 220 to electrically isolate the high-side circuit region 103 from the HV JTR 107.

The power semiconductor device 200 may comprise a plurality of NBLs and PBLs, such as the first GR PBL 201, the first GR NBL 202, the first PBL 203, the first NBL 204, the first ISO PBL 205, and the second ISO PBL 206. The plurality of NBLs and PBLs are disposed between a semiconductor substrate 120 and the DNW 210. The plurality of NBLs and PBLs may be formed by an ion-implantation process of heavily doped N-type or P-type dopants into the substrate 120. Thus, doping concentrations of the NBLs and PBLs are greater than a doping concentration of the semiconductor substrate 120.

Then, an N-type or a P-type epitaxial layer 130 is disposed on the semiconductor substrate 120. In addition, the DNW 210 may be formed by performing an ion implantation process in which lightly doped N-type dopants are implanted into the epitaxial layer 130 and followed by a drive-in annealing process at high-temperature. As a result, the DNW 210 is uniformly disposed in the epitaxial layer 130.

The first GR DPW 211, the first DPW 212, the first ISO DPW 213 and the second ISO DPW 214 may be formed by performing an ion implantation process of P-type dopants into the epitaxial layer 130. After performing the implantation process, a high-temperature annealing process may be further performed for the purpose of uniform dopants distribution.

Referring to FIG. 2, the high voltage junction termination region (HV JTR) 107 is disposed adjacent to the high-side circuit region 103. The HV JTR 107 may comprise a second high voltage structure 280 and a second guard ring (GR) 285 adjacent to the second high voltage structure 280. Both the second high voltage structure 280 and the second guard ring (GR) 285 may be electrically coupled to a second ground voltage GND2.

The second high voltage structure 280 may comprise an nLDMOS, a pLDMOS, an nEDMOS, or a pEDMOS. Herein, the high voltage nLDMOS structure may be implemented for the second high voltage structure 280. The second high voltage structure 280 may comprise a second PBL 207, a second DPW 215, a second FOX 218, a second NW 224, a second PBODY 225, a second PTOP 228, a second gate insulating layer 232, a second field plate 235, a second gate electrode 236, a second N+ drain region 247, a second P+ drain region 248, a second N+ source region 249, a second P+ body contact region 250, a third P+ body contact region 251, a second drain silicide layer 264, a field plate silicide layer 265, a second gate silicide layer 266, and a second source silicide layer 267.

Herein the second N+ drain region 247 and the second P+ drain region 248 become a third ESD self-protection structure 313 in the HV JTR 107. The second N+ source region 249 and the second P+ body contact region 250 become a fourth ESD self-protection structure 314 in the HV JTR 107.

Herein, the second PBODY 225 may extend to the second DPW 215, such that an overlapping region 225A may be disposed in the second DPW 215. The overlapping region 225A of the second DPW 215 may have a P-type doping concentration higher than a remaining region of the second DPW 215. The overlapping region 225A of the second DPW 215 may reduce a resistance. The second DPW 215 may be disposed over the second PBL 207, such that the second DPW 215 may vertically connect the second PBL 207 and the second PBODY 225.

Further, the second PBL 207, the second DPW 215 and the third P+ body contact region 251 in the second high voltage structure 280 may be disposed adjacent to the second GR region 285, so the second PBL 207 may be in direct contact with the second GR NBL 226 in the second GR region 285.

The second N+ drain region 247 and the second P+ drain region 248 are disposed in contact with each other in the second NW 224. The second field plate 235 is disposed on the second FOX 218 so as to reduce a surface electric field. The second field plate 235 may be electrically coupled to the second N+ drain region 247 and the second P+ drain region 248. Therefore, the second N+ drain region 247, the second P+drain region 248, and the second field plate 235 may be electrically coupled to one another, and a high voltage terminal VB may be connected thereto. The high voltage terminal VB may be biased by 600V or more.

The second PTOP 228 is disposed below the second FOX 218, may help reducing surface electric field between the third ESD self-protection structure 313 and the fourth ESD self-protection structure 314, and may assist in the extension of the depletion regions. The second PTOP 228 may be electrically coupled to the second PBODY 225.

The second N+ source region 249 and the second P+ body contact region 250 are disposed in contact with each other in the second PBODY 225. That is, the second gate electrode 236 may be disposed closer to the second P+ body contact region 250 rather than the second N+ source region 249.

The second gate insulating layer 232 is disposed on the second PBODY 225. The second gate electrode 236 is disposed on the second gate insulating layer 232. In addition, the third P+ body contact region 251 may be disposed in a region in which the second PBODY 225 and the second DPW 215 overlap each other.

The second gate electrode 236, the second N+ source region 249, the second P+ body contact region 250, and the third P+ body contact region 251 in the second HV structure 280 may be electrically coupled to the second ground voltage GND2, so the second HV structure 280 has no channel region. The second HV structure 280 may be a common-source configuration with a grounded gate or a grounded-gate configuration, because the second gate electrode 236 and the second N+ source region 249 may have the same ground potential.

The second guard ring 285 may comprise a second GR NBL 208, a second GR PBL 209, a second GR DPW 216, a second GR NW 226, a second GR N+region 252, and a second GR P+ region 253. The second GR N+ region 252 is disposed in the second GR NW 226. Moreover, the second GR P+ region 253 is disposed in the second GR DPW 216. The second GR NBL 208 may be in contact with the second PBL 207 and the second GR PBL 209. The second GR NW 226 may be disposed on the second GR NBL 208. The second GR DPW 216 may be disposed on the second GR PBL 209. The second GR N+ region 252 may be disposed in the second GR NW 226. The second GR P+ region 253 may be disposed in the second GR DPW 216.

All of the second gate electrode 236, the second N+ source region 249, the second P+ body contact region 250, the third P+ body contact region 251, the second GR N+ region 252, and the second GR P+ region 253 may be electrically coupled to the second ground voltage GND2 so as to be applied with the ground voltage.

The second PBL 207, the second GR NBL 208, and the second GR PBL 209 may be disposed between the semiconductor substrate 120 and the DNW 210. The second PBL 207, the second GR NBL 208, and the second GR PBL 209 may be formed by performing an ion implantation process of P-type or N-type dopants into the substrate 120 and followed by a high-temperature annealing process.

As mentioned above, the N-type or the P-type epitaxial layer 130 may be disposed on the semiconductor substrate 120. In addition, as described above, the DNW 210 may be formed by performing an ion implantation process of N-type dopants into the epitaxial layer 130 and followed by a drive-in annealing process at high-temperature for uniform dopant distribution. Here, the DNW 210 may have a doping concentration lower than a doping concentration of the second PBL 207, the second GR NBL 208, or the second GR PBL 209, so as to increase a breakdown voltage in the power semiconductor device 200.

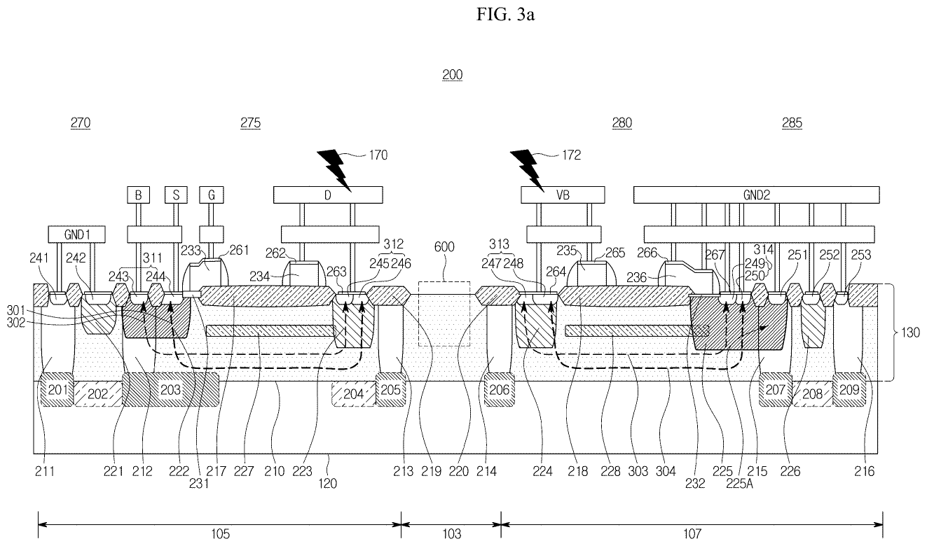

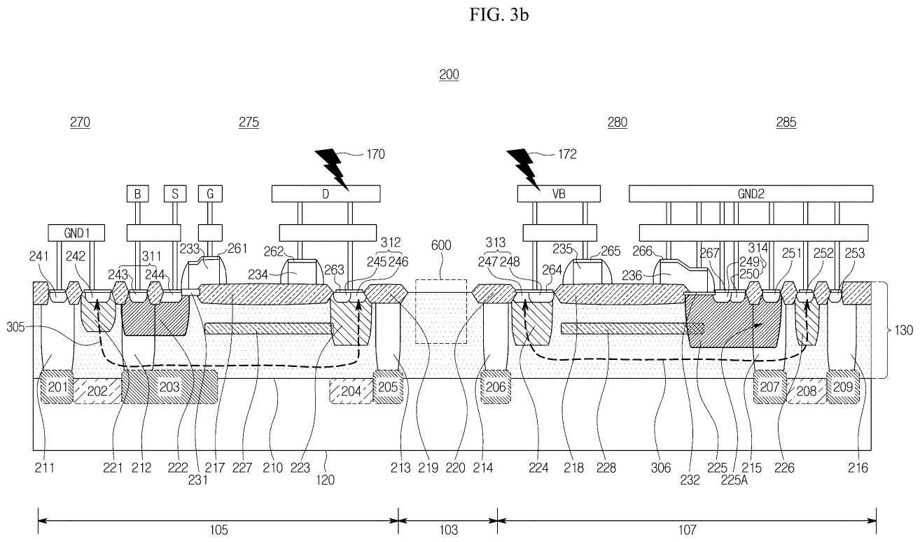

FIGS. 3a and 3b illustrate ESD current flow diagrams of the power semiconductor device, which comprises the ESD self-protection structure according to an embodiment. When an Electrostatic Discharge (ESD) surge 170 or 172 occurs and the HV LDMOS structure 275 or 280 is involved, the discharge current may attempt to find the path of least resistance to ground. The exact path depends on how the HV LDMOS structure 275 or 280 is connected in the circuit and where the ESD event occurs. The HV LDMOS structure 275 or 280 may provide SCR (Silicon Controlled Rectifier)-based ESD protection devices when the Electrostatic Discharge (ESD) surge 170 or 172 occurs.

Here are the ways to enhance the ESD capability of the first or second HV LDMOS structure 275 or 280 by incorporating SCR (Silicon Controlled Rectifier) structures. Integrating SCR structures into the first or second HV LDMOS structure 275 or 280 may significantly improve their Electrostatic Discharge (ESD) robustness. The key is to leverage the SCR's inherent high current handling capability and low on-resistance to effectively shunt ESD stresses. The SCR structure may be embedded into each of the first or second HV LDMOS structure 275 or 280. The SCR structure may have a fundamental four-layer (PNPN) structure, which is effectively similar to two bipolar structures (NPN and PNP) connected to each other. This involves directly forming the SCR structures within the drain region (or source region) of the first or second HV LDMOS structure 275 or 280 by adding a P+ doped region (or an N+ doped region). It offers better area efficiency compared to adding a separate SCR and can minimize changes to the LDMOS's DC characteristics. During an ESD event, the embedded SCR turns ON rapidly and effectively shunts the ESD current to ground. The embedded SCR structures into the first or second HV LDMOS structure 275 or 280 may be ESD self-protection structures.

Referring to FIG. 3a, in the first HV LDMOS structure 275 of the level shifter 105, as described earlier, the first ESD self-protection structure 311 may comprise the first P+ body contact region 243 and the first N+ source region 244. The second ESD self-protection structure 312 may comprise the first P+ drain region 245 and the first N+ drain region 246. Herein, the first P+ drain region 245 may be added to the drain region of the first HV LDMOS structure 275 to form a first embedded SCR structure.

Referring to FIG. 3a, in the second HV LDMOS structure 280 of the HVJTR 107, the third ESD self-protection structure 313 may comprise the second N+ drain region 247 and the second P+ drain region 248. The fourth ESD self-protection structure 314 may comprise the second N+ source region 249 and the second P+ body contact region 250. Herein, the second P+ drain region 248 may be added to the drain region of the second HV LDMOS structure 280 to form a second embedded SCR structure.

Referring to FIG. 3a, a first ESD surge discharge current path 301 and a second ESD surge discharge current path 302 may depict a first NPN path and a first PNP path, respectively, in the first HV LDMOS structure 275. Further, a third ESD surge discharge current path 303 and a fourth ESD surge discharge current path 304 may depict a second NPN path and a second PNP path, respectively, in the second HV LDMOS structure 280.

An ESD surge or event 170 may enter the second ESD self-protection structure 312, the ESD current may be discharged into the first ESD self-protection structure 311 by the first ESD surge discharge current path 301 or the second ESD surge discharge current path 302. The same applies if an ESD surge occurs in the opposite direction. The ESD surge or event 170 may enter the first ESD self-protection structure 311, the ESD current may be discharged into the second ESD self-protection structure 312 by the first ESD surge discharge current path 301 or the second ESD surge discharge current path 302. The ESD current may easily flow out through ESD self-protection structures, which are bi-directional based on a Silicon-Controlled Rectifier (SCR).

The ESD current may easily flow out through the first ESD self-protection structure 311 and the second ESD self-protection structure 312. The first ESD surge discharge current path 301 or the second ESD surge discharge current path 302 may be implemented to discharge the ESD event or surge 170. The first ESD self-protection structure 311 and the second ESD self-protection structure 312 may be referred to as the first embedded SCR structure and the second embedded SCR structure, respectively.

In addition, referring to FIG. 3a, in the second HV LDMOS structure 280 of the HV JTR 107, the ESD current may flow out by a third ESD surge discharge current path 303 in which the ESD current flows out by the second NPN path, and a fourth ESD surge discharge current path 304 in which the ESD current flows out by the second PNP path.

An ESD surge or an event 172 may enter the third ESD self-protection structure 313, the ESD current may be discharged into the fourth ESD self-protection structure 314 by the third ESD surge discharge current path 303 or the fourth ESD surge discharge current path 304. The same applies if an ESD surge occurs in the opposite direction. The ESD surge or event 172 may enter the fourth ESD self-protection structure 314, the ESD current may be discharged into the third ESD self-protection structure 313. The ESD current may easily flow out through ESD self-protection structures, which are bi-directional based on a Silicon-Controlled Rectifier (SCR).

The second N+ drain region 247 and the second P+ drain region 248 in contact with each other may be considered as the third ESD self-protection structure 313. In addition, the second N+ source region 249 and the second P+ body contact region 250 in contact with each other may be considered as the fourth ESD self-protection structure 314. The ESD current of 1 A or more may easily flow out by the third ESD self-protection structure 313 and the fourth ESD self-protection structure 314.

The third ESD self-protection structure 313 and the fourth ESD self-protection structure 314 may be referred to as a third embedded SCR structure and a fourth embedded SCR structure, because each of the third ESD self-protection structure 313 and the fourth ESD self-protection structure 314 is a structure in which the n-type and the p-type high concentration doping regions are combined, and operates bi-directionally.

Due to the embedded ESD self-protection structure, it is possible to obtain a desired ESD characteristic without a need to manufacture a separate ESD structure additionally and without increasing the area of the chips occupied by the high power semiconductor device. Well-designed SCR-based ESD protection devices can offer high ESD protection capabilities for a small silicon area. This is advantageous for improving space efficiency in integrated circuit (IC) design.

Referring to FIG. 3b, a fifth ESD surge discharge current path 305, in which the ESD current flows out through an NPN path in the level shifters 105, is illustrated. In addition, a sixth ESD surge discharge current path 306 in which the ESD current flows out through an NPN path in the HV JTR 107 is illustrated.

The ESD surge or event 170 may enter the second ESD self-protection structure 312 (the first P+ drain region 245 and the first N+ drain region 246) of the level shifters 105, the ESD current of 1 A or more may flow out into the first GR N+ region 242 of the first guard ring 270 by the fifth ESD surge discharge current path 305.

The ESD surge or event 172 may enter the third ESD self-protection structure 313 (the second N+ drain region 247 and the second P+ drain region 248) of the HV JTR 107, the ESD current of 1 A or more may flow out into second GR N+ region 252 of the second guard ring 285 by the sixth ESD surge discharge current path 306.

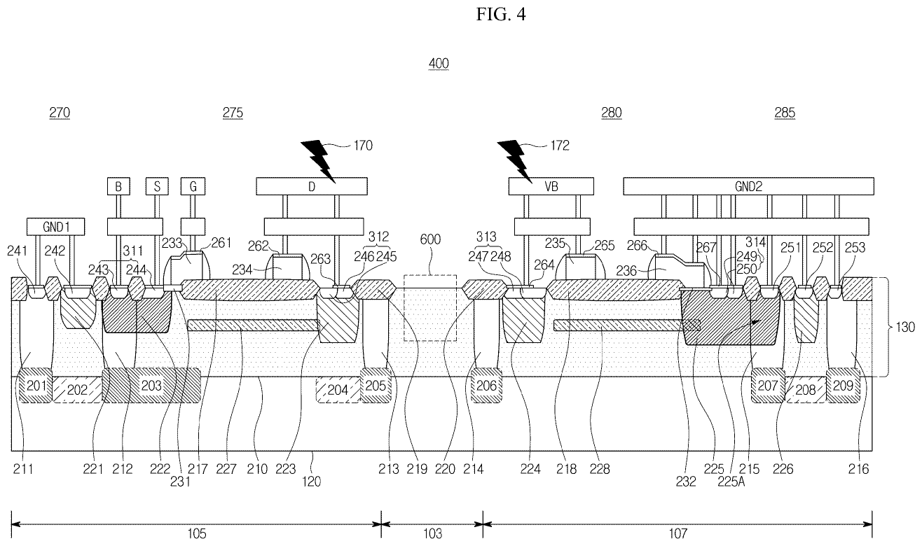

FIG. 4 illustrates a cross-sectional view of a power semiconductor device which comprises an ESD self-protection structure according to another embodiment. FIG. 4 is similar to FIG. 3, but has a difference in the length of the drain silicide layer or the source silicide layer.

In FIG. 4, the power semiconductor device 400 may comprise the first drain silicide layer 263 disposed on the first P+ drain region 245 and the first N+ drain region 246 of the level shifters 105; and the second source silicide layer 267 disposed on the second N+ source region 249 and the second P+ body contact region 250 of the HV JTR 107.

The power semiconductor device 400 may comprise the second drain silicide layer 264 disposed on the second N+ drain region 247 and the second P+ drain region 248 in contact with each other. In addition, the power semiconductor device 400 may further comprise the first gate silicide layer 261 and the second gate silicide layer 266 disposed on the first gate electrode 233 and the second gate electrode 236.

Here, the first drain silicide layer 263 may fully cover the first N+ drain region 246 and may extend on a portion of the first P+ drain region 245. The first drain silicide layer 263 may partially cover the first P+ drain region 245. The contact resistance may increase in the first high voltage structure 275. Therefore, the region with no first drain silicide layer 263 disposed thereon may be referred to as a first resistive electrical ballast region. This first resistive electrical ballast region may enhance the ESD robustness in the first high voltage structure (HV LDMOS) 275.

The second drain silicide layer 264 may fully cover the second N+ drain region 247 and may extend on a portion of the second P+ drain region 248. The second drain silicide layer 264 may partially cover the second P+ drain region 248. The contact resistance may increase in the second high voltage structure 280. Therefore, the region with no second drain silicide layer 264 disposed thereon may be referred to as a second resistive electrical ballast region. This second resistive electrical ballast region may really enhance the ESD robustness in the second high voltage structure (HV LDMOS) 280.

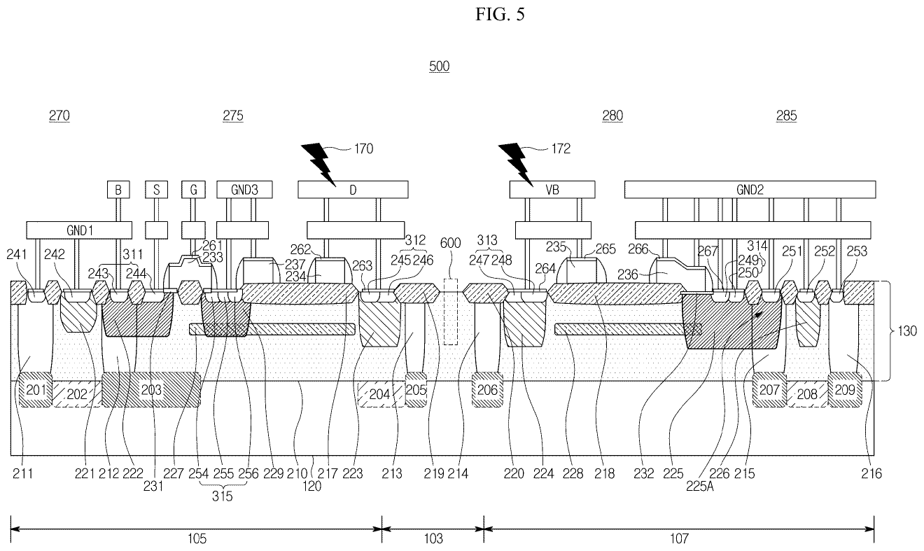

FIG. 5 illustrates a cross-sectional view of a power semiconductor device which comprises an ESD self-protection structure according to another embodiment. FIG. 5 is similar to FIG. 2, with a difference therebetween being the addition of a PBODY and a PNP region.

Referring to FIG. 5, the level shifters 105 of the power semiconductor device 500 may further comprise a third PBODY 229 disposed between the first PBODY 222 and the first NW 223. A first P+ region 254, a first N+ region 255, and a second P+ region 256 are disposed parallel to one another in the third PBODY 229. A third ground voltage GND3 may be electrically coupled to the first P+ region 254, the first N+ region 255, and the second P+ region 256. A third field plate 237 may be electrically coupled to the third ground voltage GND3.

The first PTOP 227 may overlap with the third PBODY 229, in which the first P+ region 254, the first N+ region 255, and the second P+ region 256 are disposed, so as to apply the third ground voltage GND3 to the first PTOP 227.

The power semiconductor device 500 has an advantage that the power semiconductor device 500 may add a new ESD surge discharge path by adding the first P+ region 254, the first N+ region 255, and the second P+ region 256 disposed parallel to one another in the third PBODY 229.

The ESD surge or event 170 enters the first P+ drain region 245 or the first N+ drain region 246 of the level shifters 105, the ESD current of 1 A or more may flow out into the first P+ region 254, the first N+ region 255, and the second P+ region 256.

The first P+ region 254, the first N+ region 255, and the second P+region 256 in contact with each other may be considered as a fifth ESD self-protection structure 315. In the power semiconductor device 500, the ESD current of 1 A or more may well flow out by the fifth ESD self-protection structure 315, as well as the first and the second ESD self-protection structures 311 and 312.

The fifth ESD self-protection structure 315 may be referred to as a fifth embedded SCR structure, because the fifth ESD self-protection structure 313 is a structure in which the first P+ region 254, the first N+ region 255, and the second P+ region 256 are combined, and operates bi-directionally.

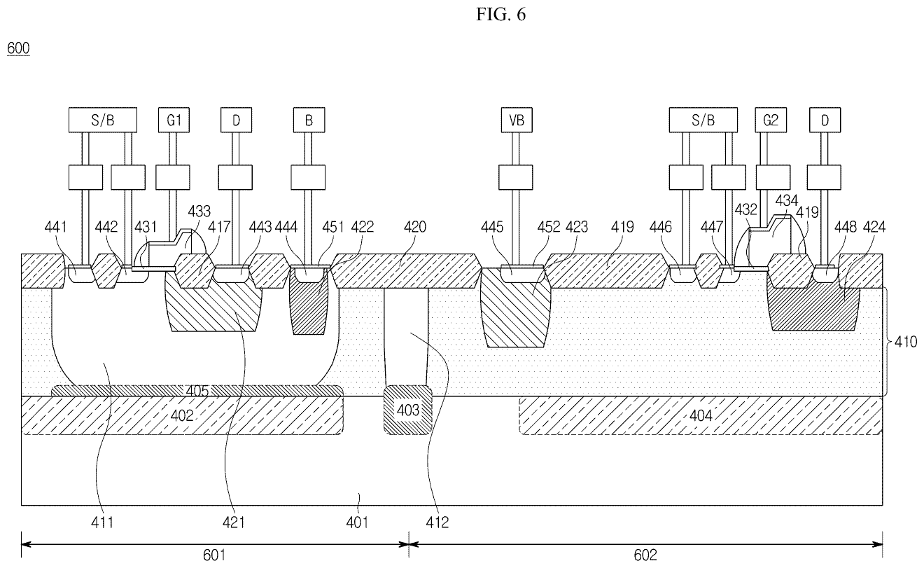

FIG. 6 illustrates a cross-sectional view of a plurality of high power semiconductor devices according to an embodiment of the present disclosure.

Referring to FIG. 6, a power semiconductor device 600 may comprise a first N-type high voltage semiconductor device 601 and a second P-type high voltage semiconductor device 602, each of which may be disposed by an N-type EDMOS (nEDMOS) structure or a P-type EDMOS (pEDMOS) structure, and operates at about 20V or more.

The first high voltage semiconductor device 601 disposed in the high-side circuit region 103 may comprise the nEDMOS. The first high voltage semiconductor device 601 may comprise a semiconductor substrate 401, an DNW 410, and a first high voltage N-type buried layer (HV NBL) 402 disposed between the semiconductor substrate 401 and the DNW 410. The first high voltage semiconductor device 601 may comprise a high voltage P-type buried layer (HV PBL) 405 disposed on the first high voltage N-type buried layer HV NBL 402; a high voltage deep P-type well region (HV DPW) 411 disposed on the HV PBL 405; and a first high voltage N-type well region (HV NW) 421 and a first high voltage P-type well region (HV PW) 422 disposed in the HV DPW 411. The first high voltage semiconductor device 601 may comprise a first HV P+ region 441 and an HV N+ source region 442 disposed in the HV DPW 411; an HV N+ drain region 443 disposed in the first HV NW 421; and a second HV P+ region 444 disposed in the first HV PW 422. In addition, the first high voltage semiconductor device 601 may comprise may comprise a first HV FOX 417 and a first HV gate insulating layer 431 disposed between the HV N+source region 442 and the HV N+ drain region 443; and a first HV gate electrode 433 disposed on the first HV FOX 417 and the first HV gate insulating layer 431 and to which a first HV gate terminal G1 is connected.

The second high voltage semiconductor device 602 disposed in the high-side circuit region 103 may comprise the pEDMOS. The second high voltage semiconductor device 602 may comprise a second HV N-type buried layer (HV NBL) 404 disposed between the semiconductor substrate 401 and the DNW 410; and a second HV N-type well region (HV NW) 423 and a second HV PW 424 disposed on the second HV NBL 404. The second high voltage semiconductor device 602 may comprise a first HV N+ region 445 disposed in the second HV NW 423; a second HV N+ region 446 and an HV P+ source region 447 disposed in the DNW 410; and an HV P+ drain region 448 disposed in the second HV PW 424. In addition, the second high voltage semiconductor device 602 may comprise a second HV FOX 419 and a second HV gate insulating layer 432 disposed between the HV P+ source region 447 and the HV P+ drain region 448; and a second HV gate electrode 434 disposed on the second HV FOX 419 and the second HV gate insulating layer 432 and to which the second HV gate terminal G2 is connected.

Silicide layers 451 and 452 may be disposed on the second HV P+ region 444 and the first HV N+ region 445, respectively. A high voltage of 600V or more (VB) may be applied to the first HV N+ region 445. A high voltage isolation P-type buried layer (HV ISO PBL) 403, a high voltage isolation deep P-type well region (HV ISO DPW) 412, and a high voltage isolation field oxide (HV ISO FOX) 420 may be disposed between the first high voltage semiconductor device 601 and the second high voltage semiconductor device 602.

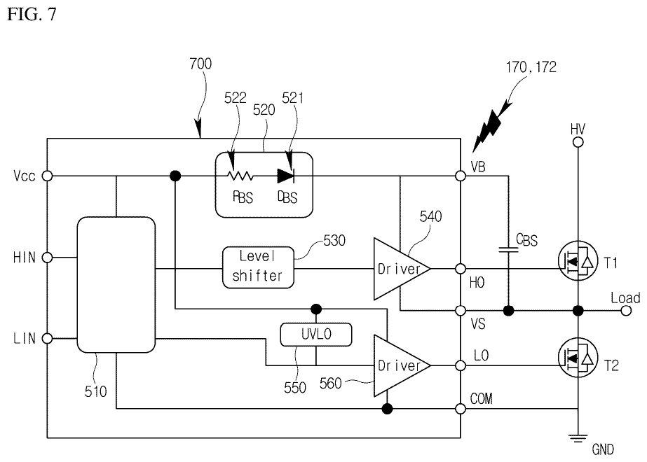

FIG. 7 illustrates a high voltage integrated circuit diagram to which an embodiment of the present disclosure can be applied.

A high voltage integrated circuit 700 illustrated in FIG. 7 may be a gate driver that provides a gate control signal to switching devices T1 and T2 according to an external control. The high voltage integrated circuit 700 may comprise a control unit 510, a bootstrap circuit 520, a level shifter circuit 530, a high-side gate driver 540, an UVLO (under voltage lockout) 550, and a low-side gate driver 560 so as to provide the gate control signal to a gate of the switching devices T1 and T2 outside.

The control unit 510 may provide a control input to the high-side gate driver 540 and the low-side gate driver 560 configured to generate the gate control signal of the switching devices T1 and T2 based on an external control signal.

The bootstrap circuit 520 may comprise a bootstrap diode 521 and a bootstrap resistance 522. According to an embodiment, the bootstrap resistance 522 may not be provided. In addition, the bootstrap diode 521 may comprise a PN diode or a Schottky diode.

The bootstrap circuit 520 may supply power for driving the first switching device T1 together with a bootstrap capacitor C_{BS} coupled to an external device.

The level shifter circuit 530 may be configured to generate, based on the set control signal, an output control signal having a first amplitude greater than a second amplitude of the input control signal. The level shifter circuit 530 may be also configured to send the output control signal to the switch driver. The output control signal transmission from the low-side circuit region 110 to the high-side circuit region 120 is performed by the level shifter circuit 530. The level shifter circuit 530 may comprise nLDMOS, pLDMOS, nEDMOS or pEDMOS.

According to an embodiment, the high-side gate driver 540 may generate a signal for controlling the first switching device T1, and the low-side gate driver 560 may generate a signal for controlling the second switching device T2.

The UVLO 550 serves to detect whether the low-side gate driver 560 is too small to operate, and to stop the operation, and the UVLO 550 may detect a low-side and stop the operation with respect to not only a voltage related to the low-side gate driver 560 illustrated in FIG. 7, but also the input voltage or a voltage related to the high-side gate driver 540.

The first switching device T1 and the second switching device T2 may be an N-type MOSFET (metal oxide semiconductor field effect structure) or an IGBT (insulated gate bipolar structure).

The first switching device T1 is provided between a high voltage HV and a load, and a source may be coupled to the high voltage HV, and a drain may be coupled to the load. A gate of the first switching device T1 may be coupled to a high-side output terminal HO of the high voltage integrated circuit 700, thereby the first switching device T1 may be turned on or off by a voltage output from the high-side output terminal HO. When the first switching device T1 is turned on, the first switching device T1 may output the high voltage HV to the load.

The second switching device T2 may be provided between the ground voltage GND and the load, a source is coupled to a load, and a drain is coupled to a ground voltage GND. A gate of the second switching device T2 is coupled to the low-side output terminal LO of the high voltage integrated circuit 700, thereby the second switching device T2 may be turned on or off by a voltage output from the low-side output terminal LO. When the second switching device T2 is turned on, the second switching device T2 may output the ground voltage GND to the output terminal (load).

The drain of the first switching device T1 and the source of the second switching device T2 together may be coupled to the load.

Referring to FIG. 7, for receiving or sending a signal from/to an external device and for receiving power for drive, the high voltage integrated circuit 700 may comprise a voltage input terminal Vcc, a high-side control input terminal HIN, a low-side control input terminal LIN, a ground terminal COM, a high voltage terminal VB, a high voltage return voltage terminal VS, the high-side output terminal HO, and the low-side output terminal LO.

The high voltage integrated circuit 700 may receive power desired for drive through the voltage input terminal Vcc, and may be coupled to an external ground voltage GND through the ground terminal COM to form the ground common with an external device.

The high voltage integrated circuit 700 may output a high-side control signal which controls an operation of the first switching device T1 through the high-side output terminal HO, in response to a logic signal input through the high-side control input terminal HIN.

The high-side output terminal HO may be coupled to the gate of the first switching device T1, and may control a switching operation of the first switching device T1.

The high voltage integrated circuit 700 may output a low-side control signal which controls an operation of the second switching device T2 through the low-side output terminal LO, in response to a logic signal input through the low-side control input terminal LIN. The low-side output terminal HO may be coupled to the gate of the second switching device T2, and may control a switching operation of the second switching device T2.

The first switching device T1 and the second switching device T2 may be controlled not to be turned on at the same time. For example, when the first switching device T1 is controlled to be turned on, the second switching device T2 may be controlled to be turned off. Alternatively, when the first switching device T1 is controlled to be turned off, the second switching device T2 may be controlled to be turned on.

The bootstrap capacitor C_{BS} may be coupled between the high voltage terminal VB and the high voltage return voltage terminal VS. In addition, the high voltage return voltage terminal VS may be coupled to the load, the drain of the first switching device T1 and the source of the second switching device T2.

The bootstrap diode 521 in the high voltage integrated circuit 700 and the bootstrap capacitor C_{BS} outside thereof may be coupled in series. An anode of the bootstrap diode 521 may be coupled to a driving power supplied through the voltage input terminal Vcc by going through the bootstrap resistance 522, and one end of the bootstrap capacitor C_{BS} (e.g.: a cathode) may be coupled to the load, the high voltage return voltage terminal VS, the drain of the first switching device T1, and the source of the second switching device T2. In addition, the cathode of the bootstrap diode 521 and another end of the bootstrap capacitor C_{BS} are coupled to each other, and the coupled spot may supply the driving power to the high-side gate driver 540.

When the second switching device T2 is turned on and the first switching device T1 is turned off, a voltage applied to the one end of the bootstrap capacitor C_{BS} becomes the ground voltage GND, and a forward voltage is applied to the bootstrap diode 521, and a forward bias current flows therein. Because of the forward bias current, a voltage obtained by subtracting a voltage applied to the bootstrap resistance 522 and a threshold voltage of the bootstrap diode 521 from the driving voltage input through the voltage input terminal Vcc is applied to the high voltage terminal VB. The bootstrap capacitor C_{BS} may be charged by a voltage output from the high voltage terminal VB.

When the first switching device T1 is turned on and the second switching device T2 is turned off, a voltage applied to the one end of the bootstrap capacitor C_{BS} becomes a great high voltage HV greater than the driving voltage Vcc, and a reverse voltage is applied to the bootstrap diode 521, thereby a flow of the current may be blocked by the bootstrap diode 521. At this instance, a voltage of a value obtained by adding a charged voltage in the bootstrap capacitor C_{BS} to the high voltage HV applied to the one end of the bootstrap capacitor C_{BS} is applied to the high voltage terminal VB. As this voltage drives the high-side gate driver 540 and is output to the high-side output terminal HO, a voltage between the source and the gate of the first switching device T1 may become a charging voltage of the bootstrap capacitor C_{BS}. The charging voltage is greater than a threshold voltage of the first switching device T1, and thus, the charging voltage may stably drive the first switching device T1.

It is needed to design the high voltage integrated circuit 700 such that an internal circuit or the power semiconductor device is not damaged when the ESD 170 and 172 enter the high voltage terminal VB. The present disclosure proposes the power semiconductor device which is strong to the ESD and is designed such that a high current due to the ESD 170 and 172 flows well by forming the silicon-controlled rectifier (SCR) structure embedded with the above-described self-ESD protection function.

According to an embodiment of the present disclosure, it is possible to provide an HVIC semiconductor device including a level shifter having a self-ESD. With this configuration, it is possible to provide an HVIC semiconductor device capable of improving the ESD characteristics without allowing the area of chips to increase.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power semiconductor device, comprising:
a low-side circuit region and a high-side circuit region disposed on a semiconductor substrate;
a junction termination region disposed between the low-side circuit region and the high-side circuit region;
a high voltage lateral double diffused metal oxide semiconductor (HV LDMOS) structure disposed in the junction termination region; and
a first power semiconductor device and a second power semiconductor device disposed in the high-side circuit region;
wherein the HV LDMOS structure comprises:
a first P-type buried layer (PBL) disposed on the semiconductor substrate;
a first P-type body region (PBODY) disposed above the first PBL;
a first deep P-type well region (DPW) connecting the first PBL and the first PBODY;
a first N-type well region (NW) spaced apart from the first PBODY;
a first highly doped P-type (P+) body contact region disposed in the first PBODY;
a first highly doped N-type (N+) source region disposed in the first PBODY; and
a first N+ drain region and a first P+ drain region disposed in contact with each other in the first NW.

2. The power semiconductor device of claim 1, wherein the HV LDMOS structure further comprises:
a deep N-type well region (DNW) disposed on the semiconductor substrate;
a first field oxide layer (FOX) and a first gate insulating layer disposed between the first N+ source region and the first N+ drain region;
a first gate electrode disposed on a portion of the first FOX and the first gate insulating layer;
a first field plate disposed on another portion of the first FOX and electrically coupled to the first N+ drain region and the first P+ drain region;
a first P-type top region (PTOP) disposed below the first FOX; and
a first N-type buried layer (NBL) disposed below the first NW, the first N+ drain region, and the first P+ drain region.

3. The power semiconductor device of claim 1, wherein the junction termination region comprises:
a second PBL disposed on the semiconductor substrate;
a second PBODY disposed above the second PBL;
a second DPW connecting the second PBL and the second PBODY;
a second NW spaced apart from the second PBODY;
a second N+ source region and a second P+ body contact region disposed in contact with each other in the second PBODY;
a second N+ drain region and a second P+ drain region disposed in contact with each other in the second NW;
a second FOX and a second gate insulating layer disposed between the second N+ source region and the second N+ drain region;
a second gate electrode disposed on a portion of the second FOX and the second gate insulating layer;
a second field plate disposed on the second FOX and electrically coupled to the second N+ drain region and the second P+ drain region; and
a second PTOP disposed below the second FOX.

4. The power semiconductor device of claim 1, further comprising a first guard ring (GR) adjacent to the HV LDMOS structure, and the first GR comprising:
a first GR N-type buried layer (NBL) disposed on the semiconductor substrate;
a first GR P-type buried layer (PBL) disposed on the semiconductor substrate;
a first GR N-type well region (NW) disposed on the first GR NBL;
a first GR deep P-type well region (DPW) disposed on the first GR PBL;
a first GR N+ region disposed in the first GR NW; and
a first GR P+ region disposed in the first GR DPW.

5. The power semiconductor device of claim 4, further comprising a second GR disposed in the junction termination region, the second GR comprising:
a second GR NBL disposed on the semiconductor substrate;
a second GR PBL disposed on the semiconductor substrate;
a second GR NW disposed on the second GR NBL;
a second GR DPW disposed on the second GR PBL;
a second GR N+ region disposed in the second GR NW; and
a second GR P+ region disposed in the second GR DPW.

6. The power semiconductor device of claim 1, further comprising:
a first isolation region disposed between the HV LDMOS structure and the high-side circuit region; and
a second isolation region disposed between the high-side circuit region and the junction termination region,
wherein each of the first isolation region and the second isolation region comprises:
an isolation P-type buried layer (ISO PBL) disposed over the semiconductor substrate;
an isolation deep P-type well region (ISO DPW) disposed on the ISO PBL; and
an isolation field oxide layer (ISO FOX) disposed on the ISO DPW.

7. The power semiconductor device of claim 3, further comprising:
a first silicide layer disposed on the first N+ drain region and the first P+ drain region of the HV LDMOS structure; and
a second silicide layer disposed on the second N+ source region and the second P+ body contact region of the junction isolation region,
wherein the first N+ drain region is fully covered by the first silicide layer, and the first P+ drain region is partially covered by the first silicide layer, and
wherein the second P+ body contact region is fully covered by the second silicide layer, and the second N+ source region is partially covered by the second silicide layer.

8. The power semiconductor device of claim 1, wherein the HV LDMOS structure further comprises:
a third PBODY disposed between the first PBODY and the first NW; and
a first P+ region, a first N+ region and a second P+ region disposed in the third PBODY.

9. The power semiconductor device of claim 1, wherein the first power semiconductor device is an N-type extended drain metal oxide semiconductor (nEDMOS) structure comprising:
a first high voltage N-type buried layer (HV NBL) disposed on the semiconductor substrate;
a first high voltage P-type buried layer (HV PBL) disposed on the first HV NBL;
a high voltage deep P-type well region (HV DPW) disposed on the first HV PBL;
a HV N+ source region and an HV N+ drain region disposed in the HV DPW;
a first HV gate insulating layer disposed between the HV N+ source region and the HV N+ drain region; and
a first HV gate electrode disposed on the first HV gate insulating layer.

10. The power semiconductor device of claim 1, wherein the second power semiconductor device is a P-type extended drain metal oxide semiconductor (pEDMOS) structure comprising:
a second HV NBL disposed on the semiconductor substrate;
an HV deep N-type well region (HV DNW) disposed on the second HV NBL;
a HV P+ source region and a HV P+ drain region disposed in the HV DNW;
a second HV gate insulating layer disposed between the HV P+ source region and the HV P+ drain region; and
a second HV gate electrode disposed on the second HV gate insulating layer.

11. A power semiconductor device, comprising:
a low-side circuit region and a high-side circuit region disposed on a semiconductor substrate;
a junction termination region disposed between the low-side circuit region and the high-side circuit region;
a high voltage lateral double diffused metal oxide semiconductor (HV LDMOS) structure disposed in the junction termination region; and
a first power semiconductor device and a second power semiconductor device disposed in the high-side circuit region;
wherein the HV LDMOS structure comprises:
a first P-type buried layer (PBL) disposed on the semiconductor substrate;
a first P-type body region (PBODY) disposed above the first PBL;
a first deep P-type well region (DPW) connecting the first PBL and the first PBODY;
a first N-type well region (NW) spaced apart from the first PBODY;
a first ESD self-protection structure disposed in the first PBODY; and
a second ESD self-protection structure, disposed in the first NW, comprising a first P+ drain region forming a first embedded SCR structure.

12. The power semiconductor device of claim 11, wherein the second ESD self-protection structure further comprises a first N+ drain region and the first P+ drain region disposed in contact with each other in the first NW.

13. The power semiconductor device of claim 11, wherein the first ESD self-protection structure comprises a first highly doped P-type (P+) body contact region disposed in the first PBODY, and a first highly doped N-type (N+) source region disposed in the first PBODY.

14. The power semiconductor device of claim 11, wherein the junction termination region comprises:
a second PBL disposed on the semiconductor substrate;
a second PBODY disposed above the second PBL;
a second DPW connecting the second PBL and the second PBODY;
a second NW spaced apart from the second PBODY;
a second N+ source region and a second P+ body contact region disposed in contact with each other in the second PBODY;
a second N+ drain region and a second P+ drain region disposed in contact with each other in the second NW;
a second FOX and a second gate insulating layer disposed between the second N+ source region and the second N+ drain region;
a second gate electrode disposed on a portion of the second FOX and the second gate insulating layer;
a second field plate disposed on the second FOX and electrically coupled to the second N+ drain region and the second P+ drain region; and
a second PTOP disposed below the second FOX.
